(19) United States
(12) Patent Application Publication
(10) Pub. No.: US 2012/0211895 A1
(43) Pub. Date: Aug. 23, 2012

(54) CHIP MODULE AND METHOD FOR PROVIDING A CHIP MODULE

(75) Inventors: Bernhard LANGE, Freising (DE); Thies PUCHERT, Langenbach (DE)

(73) Assignee: TEXAS INSTRUMENTS DEUTSCHLAND GMBH, Freising (DE)

(21) Appl. No.: 13/366,607

(22) Filed: Feb. 6, 2012

(30) Foreign Application Priority Data
Feb. 23, 2011 (DE) 102011012186.2

(51) Int. Cl. H01L 23/538; H01L 21/56

(52) U.S. Cl. 257/774; 438/127; 257/E23.174; 257/E21.502

(57) ABSTRACT

A semiconductor device comprising a semiconductor die that is embedded in a package, wherein the die has a front side comprising a plurality of pads to be bonded to terminals of the package, and wherein a backside of the die is coupled to a backside surface of the package by a thermal bridge.

### CROSS-REFERENCE TO RELATED APPLICATION

This application claims priority under 35 U.S.C. 119 to German Application Number DE10 2011 012 186.2 filed on Feb. 23, 2011, hereby incorporated in its entirety herein by reference.

### FIELD

The invention relates in general to integrated circuits and more specifically to a chip module comprising a semiconductor die that is embedded in a PCB-substrate and to a method for providing a chip module.

### BACKGROUND

Modern semiconductor devices have a high packing and power density, accordingly, heat dissipation is an important issue. Thermal properties of the package are especially crucial for chip modules comprising a plurality of integrated circuits and/or semiconductor devices. Chip modules come in a variety of different forms depending on the complexity and development philosophies of their designers. These can range from using pre-packed integrated circuits on a small printed circuit board (PCB) to fully custom chip packages integrating many chips dies on a high density interconnection substrate. Chip or multichip modules are also known as a system in package or a chip stack.

FIG. 1 is a simplified cross-sectional view of a chip module 20 according to the prior art, before the embedding in a PCB-material. A thinned silicon die 2 having an active front side 3 comprising a plurality of pads or contact pads 4 is glued with non-conductive glue 6 to a PCB-substrate 8. Subsequently, the glue 6 is cured and the silicon die 2 is embedded in a PCB-substrate material 10 of FIG. 2.

FIG. 2 is a further simplified cross-sectional view of the chip module 20 known from FIG. 1. The silicon die 2 is embedded inside the PCB-substrate material 10. Preferably, a fiber reinforced plastics material is applied for embedding. A backside 12 of this package may be used for further routing of traces inside the chip module 20. The chip module 20 may be a package for a single silicon die 2 or even a multi chip package comprising a plurality of dies, semiconductor devices and/or passive components being embedded therein. The contact pads 4 at the active front side of the silicon die 2 are connected to the printed circuit board 8 by suitable connections 14, according to FIG. 2, the vias for contacting the contact pads 4 are filled with copper.

For mobile devices, modern chip modules having a small size and a high packing density have been developed. Especially for these modern packages, thermal coupling between the semiconductor die or a plurality of dies and the outside of the chip module is an important issue.

### SUMMARY

It is an object of the invention to provide a chip module and a method for providing a chip module that are improved with respect to thermal coupling between a surface of the chip module and a semiconductor die that is embedded in the chip module.

In an aspect of the invention, a chip module comprising a semiconductor die that is embedded in a printed circuit board-substrate (PCB-substrate) is provided. The die has a backside and an active front side comprising a plurality of contact pads, wherein the backside of the die is coupled to a surface of the chip module via a thermal bridge. Preferably, the backside of the die is a grinded surface that is a result of a grinding process for decreasing the thickness of the die to a desired value.

Advantageously, the thermal coupling between the embedded semiconductor die and a surface of the chip module is improved and higher heat dissipation is provided. Consequently, a higher integration density or more power integration is possible.

In another aspect of the invention, at least a portion of the backside of the die is coated with a thermally highly conductive coating. An inner end portion of the thermal bridge is adjacent to this coating. Preferably, the coating extends over the entire surface of the backside of the die. The coating may be a closed layer or a patterned layer, wherein according to another aspect, the density of the pattern may by varying. In other words, the density of the pattern may be higher in some areas of the backside of the die when compared to an average density or to a density of the pattern in the rest of the surface. According to an aspect of the invention, the density of the pattern is higher in a region of the die that produces more heat compared to other regions, e.g. the pattern density is increased in an area comprising the power transistors. A preferred material for the coating is a metal, preferably a thermally highly conductive metal e.g. copper. Advantageously, an additional copper metallization on the wafer backside improves heat dissipation from the die into the thermal bridge. Preferably, the copper layer is deposited after grinding the wafer to its final thickness. A closed layer provides the highest heat dissipation; however, it may also put mechanic stress to the die. A structured layer is advantageous due to its lower mechanical stress impact. Preferable patterned layers are dots or cross hatched lines. Further, the thermally highly conductive coating may be limited to some areas of the backside of the die, preferably areas offering a high thermal output like, e.g. the output transistors.

In another aspect of the invention, the thermal bridge is a monolithic block laterally extending over at least the entire surface of the backside of the die. Preferably, the monolithic block is made from a thermally highly conductive material that is e.g. filled with a thermally highly conductive particles. The material of the monolithic block may be filled with metal particles or metal clusters, further preferably a thermally highly conductive metal such as copper is applied. Advantageously, a monolithic block provides an effective thermal bridge for heat transfer between the backside of the semiconductor die and the outside of the chip module. Further, the generation of the monolithic block may be integrated into the embedding process easily.

According to another embodiment of the invention, the thermal bridge comprises a plurality of thermally highly conductive channels, wherein each channel provides a thermal bridge between the backside of the die and a surface of the chip module. Preferably, the thermally highly conductive channels are vias that are filled with a thermally highly conductive material preferably a thermally highly conductive metal such as copper. The vias or bores may be drilled from a surface, preferably a backside surface of the chip module down to the die or at least down to a region near to the backside surface of the die. Drilling may be performed e.g. by mechanical drilling or by laser drilling.

According to another advantageous aspect of the invention, at least a portion of the surface of the chip module is coated with a thermally highly conductive outside coating. An outer end portion of the thermal bridge is adjacent to the outside coating. This outside coating of the chip module allows improving heat dissipation from the package into a heat sink e.g. a customer printed circuit board or a part of the same. The coating is preferably made from a thermally highly conductive metal; a preferred metal is copper due to its high thermal conductivity. The backside coating or plating may be coupled to a heat sink by help of a suitable glue or solder.

In another aspect of the invention, the backside of the semiconductor die may be electrically contacted via the thermal bridge. Advantageously, this electric contact may be provided by a metal for filling the vias or bores or by a thermally highly conductive material for providing the monolithic block.

According to another aspect of the invention, a method for providing a chip module is provided. The method comprises the steps of: contacting contact pads at a front side of a semiconductor die and embedding the semiconductor die in a PCB-substrate. Drilling a plurality of vias in a backside of the PCB-substrate that is averted from the front side of the semiconductor die and filling the vias with a thermally highly conductive material so as to form a thermal bridge between the backside of the die and a surface of the chip module. Preferably, a thermally highly conductive metal, e.g. copper, is applied.

It is understood, a backside of the semiconductor die that is averted from its active front side may be thermally coupled/contacted to an outside surface of the chip module before electrically contacting the active front side of the die.

According to an advantageous embodiment, the method further comprises the step of coating at least a part of the backside of the semiconductor die so as to form a thermally highly conductive layer.

Same or similar advantages already mentioned for the semiconductor device according to the invention apply to the method for packing the semiconductor die.

### BRIEF DESCRIPTION OF THE DRAWINGS

Having thus described the invention in general terms, reference will now be made to the accompanying drawings, which are not necessarily drawn to scale, and wherein:

FIG. 1 is a cross-sectional view of an exemplary chip module according to the prior art before embedding in a PCB-material.

FIG. 2 is a further cross-sectional view to an exemplary chip module from FIG. 1 according to the prior art.

FIG. 3 is a simplified cross-sectional view of a chip module according to an embodiment of the invention.

FIG. 4 is a further simplified cross-sectional view of a chip module structure of FIG. 3 as embedded into a suitable PCB-material according to an embodiment of the invention.

FIG. 5 is a further simplified cross-sectional view to the chip module that is known from FIG. 4 according to a further processing step of creating vias according to an embodiment of the invention.

FIG. 6 is a further simplified cross-sectional view to the chip module that is known from FIG. 5 according to a further processing step where the vias are filled according to an embodiment of the invention.

FIG. 7 is another simplified cross-sectional view illustrating a further processing step according to an embodiment of the invention.

FIG. 8 is a further cross-sectional view of the chip module according to an embodiment of the invention depicted upside down relative to FIGS. 3-7.

FIG. 9 shows a chip module that is mounted on a customer printed circuit board in another simplified cross-sectional view and

FIG. 10 is further simplified cross-sectional views of a chip module according to another embodiment of the invention where a filled PCB substrate-material provides a thermal bridge as monolithic block.

FIG. 11 is a further simplified cross-sectional views of a chip module according to another embodiment of the invention showing the resulting package

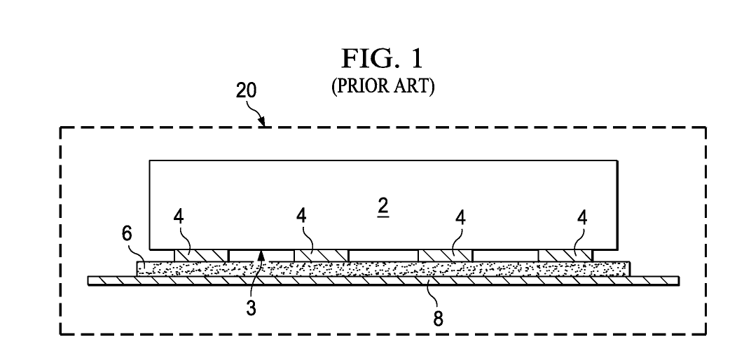

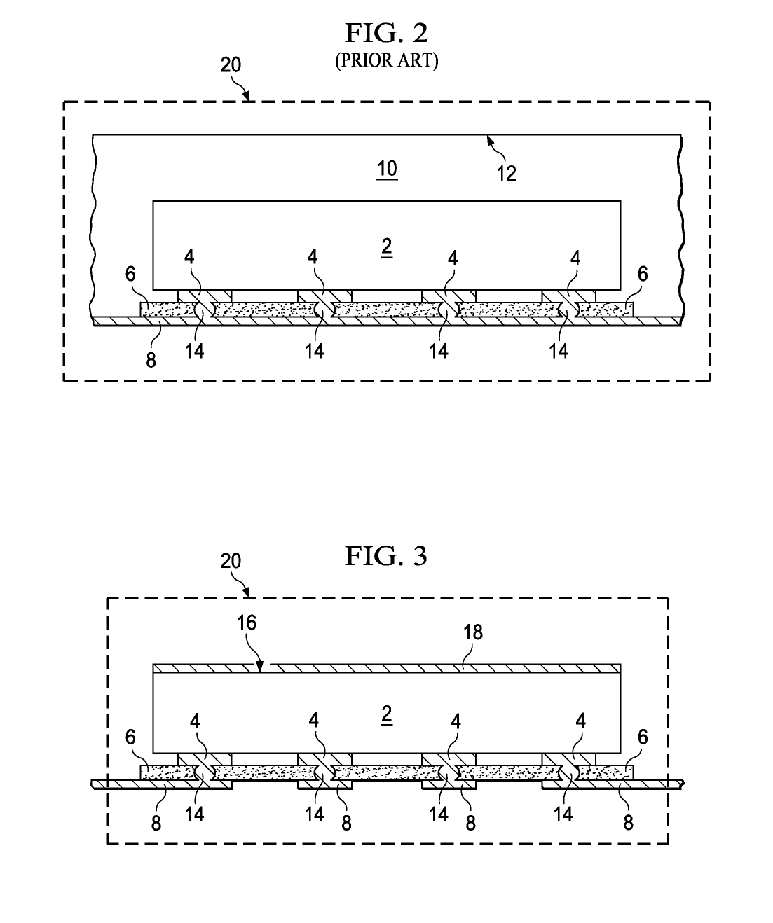

### DETAILED DESCRIPTION OF AN EXAMPLE EMBODIMENT

FIG. 3 is a simplified cross-sectional view of a chip module 20 according to an embodiment of the invention. A semiconductor die 2 having a plurality of contacting pads 4 is mounted on a PCB-substrate 8 by applying a suitable glue 6. Bores or holes are drilled in the glue 6, preferably using a laser and are subsequently filled with copper, in order to provide suitable connections 14. A grinded backside 16 of the die 2 is coated with a thermally highly conductive coating 18. Preferably, the coating is a metal coating, wherein copper is a preferable metal. The coating may extend over the entire backside 16 of the semiconductor die 2, as it is illustrated in FIG. 3. However, the coating 18 may also be patterned, e.g. by help of dots or cross hatched lines. The coating may also be limited to a specific area of the backside 16 of the semiconductor die 2 that is preferably in vicinity to heat generating parts of the die 2, e.g. the power transistors. This is because heat losses of the power transistors shall dissipate to a heat sink to prevent overheating.

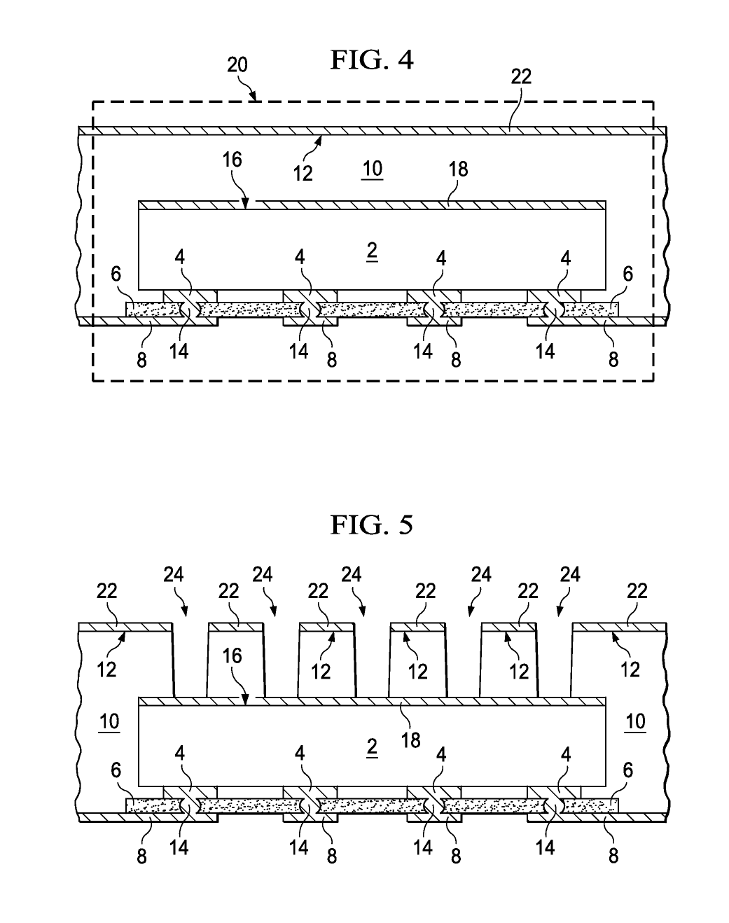

In a further step that is illustrated in FIG. 4, the structure of FIG. 3 is embedded into a suitable PCB-material 10. The backside 12 of the chip module 20 is coated with a suitable outside coating 22, preferably, a thermally highly conductive layer, e.g. a copper layer is applied. The outside coating 22 may extend over the entire surface of the package or may be patterned. Advantageously, a patterned layer may be used for providing additional electrical connections in a later process step. Alternatively, the coating may be restricted to a certain portion or area of the backside 12 of the package.

FIG. 5 is a further simplified cross-sectional view to the chip module 20 that is known from FIG. 4. According to a further processing step, holes or bores 24 are drilled in the outside coating 22 and the PCB-substrate material 10 down to the backside coating 18 of the semiconductor die 2. The bores or vias 24 may be drilled by mechanical drilling, by laser drilling or by a combination thereof.

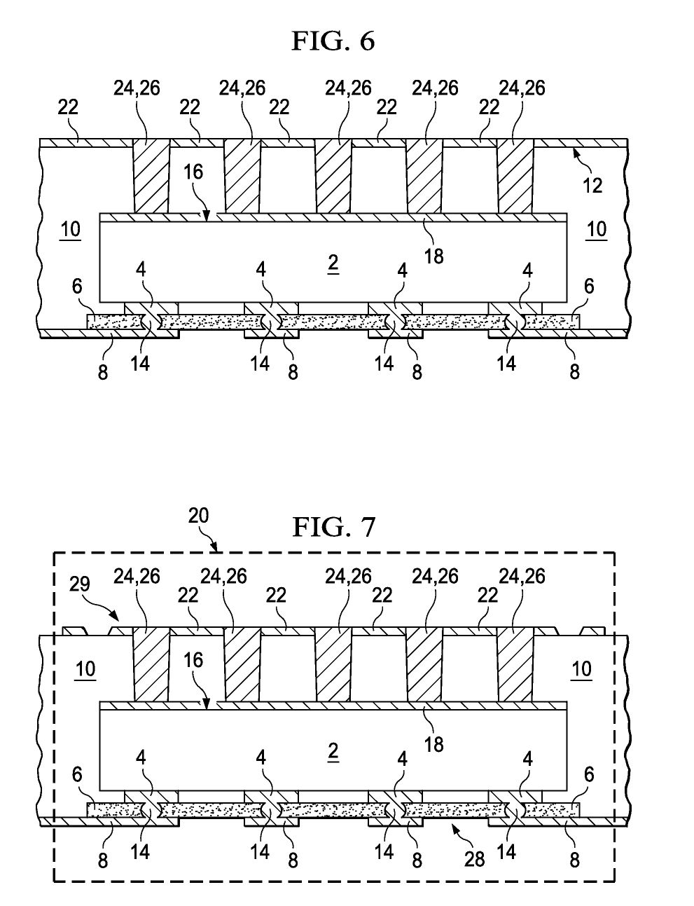

In a further processing step, shown in FIG. 6, the vias 24 are filled up with a thermally highly conductive filling material 26, preferably they are filled with a metal, e.g. with copper. The plurality of filled vias 24, i.e. the filling material 26, provide a thermal bridge between the semiconductor die 2 and the backside 12 of the chip module 20 and its outside coating 22, respectively.

FIG. 7 is another simplified cross-sectional view illustrating a further processing step. An active front side 28 of the chip module 20 is structured in a conventional way. The backside 29 is left completely with the copper outside coating 22 and the highly conductive filling material 26, respectively. It is also possible to segment the backside 29 of the package for better heat transfer, for reduction of mechanical stress or for additional electrical signal routing.

Further, an electric contact between the backside 29 of the chip module 20 and a backside 16 of the semiconductor die 2 may be provided by the filled vias 24. The thermally highly conductive filling material 26 that is preferably copper is also suitable for providing an electric contact at the same time.

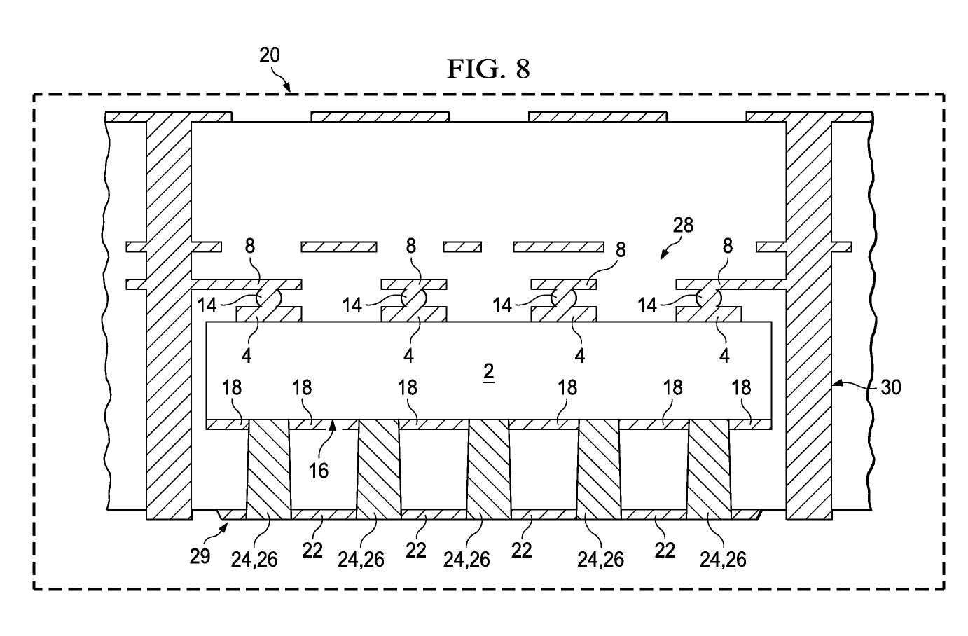

FIG. 8 is a further cross-sectional view of the chip module 22 according to an embodiment of the invention. In comparison to the aforementioned figures, the chip module 20 is depicted upside down, i.e. the thermal bridge is located at the bottom side. The pads 4 of the semiconductor die 2 are connected to a contacting layer 30 inside the package. Above this layer 30 there is further space for other components of the chip module 22. This further space may also by used for electrical signal routing and interconnections inside the chip module 20 or for connections to the pads 4 of the die 2.

There are mainly two way for assembling the chip module 20. First, the die 2 may be placed onto a PCB-substrate 8 and electric and thermal coupling is provided according to FIGS. 3 to 7. After these production steps, the PCB-substrate 8 is flipped and afterwards embedded in the chip module 20 with its thermally coupled backside 16 upside down, as it is illustrated in FIG. 8. Second, the thermal coupling may be made up before electrically contacting the semiconductor die 2. Accordingly, the die 2 may be embedded in the chip module 20 with its grinded backside upside down and the thermal bridge is manufactured by drilling and filling vias. Afterwards, the contacts pads 4 at the active front side of the die 2 are contacted.

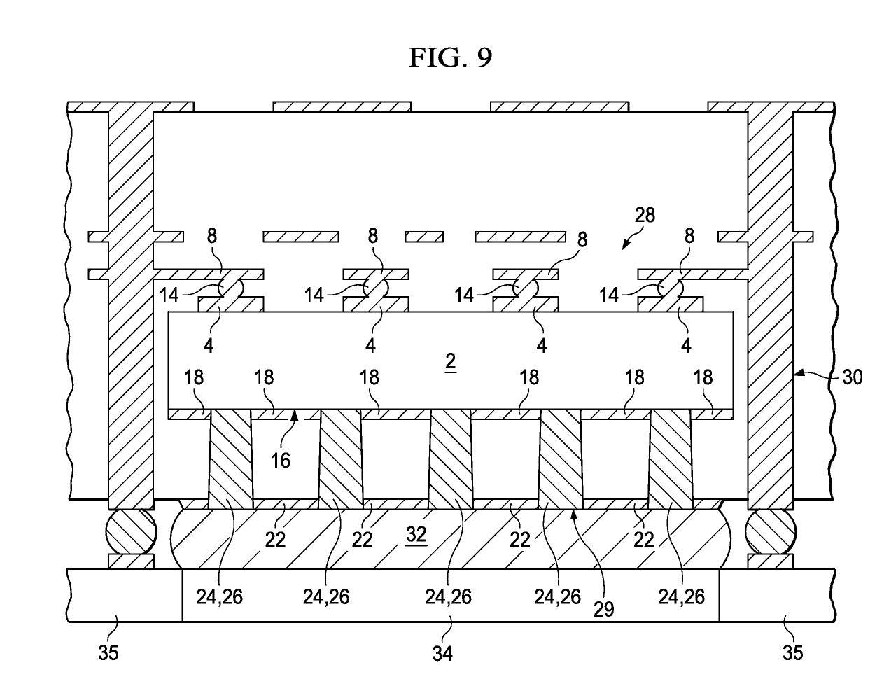

In another simplified cross-sectional view of FIG. 9 the chip module 20 of FIG. 8 is mounted to a customer printed circuit board 35. The chip module 20 is soldered by a suitable solder 32 to a heat sink 34 that is a part of the customer printed circuit board 35. The heat sink may be a metallic block that is embedded in the printed circuit board 35. The thermally highly conductive material 26 inside the vias 24 provides a thermal bridge between the backside 16 of the semiconductor die 2 and the heat sink 34.

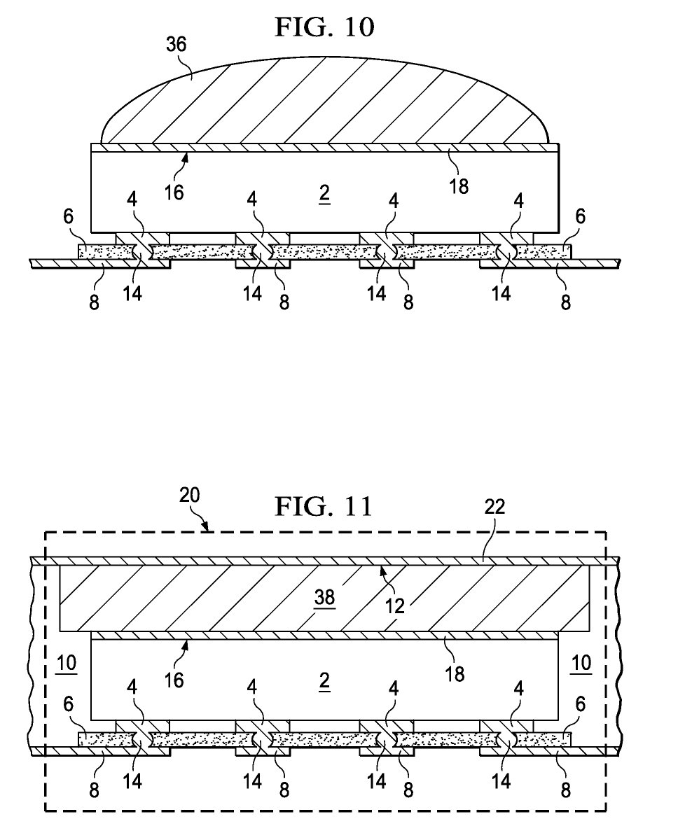

According to another embodiment of the invention that is shown in a further simplified cross-sectional view of FIG. 10, a filled PCB substrate-material 36 is used to provide a thermal bridge 38 between the backside coating 18 of the semiconductor die 2 and an outside surface of the chip module 22. The thermally highly conductive PCB substrate-material 36 is preferably filled with metal particles or clusters in order to achieve the desired thermal properties. The thermal bridge 38 may be provided by a thermally highly conductive paste too. The embedding process itself is comparable to a conventional embedding process. The resulting package, i.e. the resulting chip module 22 is shown in FIG. 11. A monolithic block 38 provides a thermal coupling between the backside of the semiconductor die 2 and the backside 12 of the package or the chip module 20, respectively. An outside coating 22 may be deposited to the backside 12 of the package to improve heat dissipation.

As already mentioned, the thermal coupling may be made up before electrically contacting the semiconductor die 2. Advantageously, a transparent thermally highly conductive PCB substrate-material 36 may be applied for manufacturing the thermal bridge 38. This allows aligning the semiconductor die 2 to an exact position for electrically contacting the active front side.

Many modifications and other embodiments of the invention will come to mind to one skilled in the art to which this invention pertains having the benefit of the teachings presented in the foregoing descriptions, and the associated drawings. Therefore, it is to be understood that the invention is not to be limited to the specific embodiments disclosed. Although specific terms are employed herein, they are used in a generic and descriptive sense only and not for purposes of limitation.

What is claimed is:

1. A chip module comprising:
a semiconductor die that is embedded in a printed circuit board-substrate (PCB-substrate), wherein the die has a backside and an active front side comprising a plurality of contact pads, wherein the backside of the die is coupled to a surface of the chip module by a thermal bridge.

2. The chip module according to claim 1, wherein at least a portion of the backside of the die is coated with a thermally highly conductive coating and an inner end portion of the thermal bridge is adjacent to the coating.

3. The chip module according to claim 2, wherein the thermal bridge is a monolithic block laterally extending over at least the entire surface of the backside of the die.

4. The chip module according to claim 3, wherein the monolithic block is made from a material that is filled with a thermally highly conductive material.

5. The chip module according to claim 1, wherein the thermal bridge comprises a plurality of thermally highly conductive channels, each providing a thermal bridge between the backside of the die and the surface of the chip module.

6. The chip module according to claim 5, wherein the thermally highly conductive channels are vias that are filled with a thermally highly conductive material.

7. The chip module according to clam 1, wherein at least a portion of the surface of the chip module is coated with a thermally highly conductive outside coating and an outer end portion of the thermal bridge is adjacent to the outside coating.

8. The chip module according to claim 1, wherein an electric contact between the surface of the chip module and the backside of the die is provided via the thermal bridge.

9. A method for providing a chip module comprising:
contacting contact pads at a front side of a semiconductor die and embedding the semiconductor die in a PCB-substrate;
drilling a plurality of vias in a surface of the PCB-substrate that is averted from the front side of the semiconductor die; and
filling the vias with a thermally highly conductive material so as to form a thermal bridge between the backside of the die and the surface of the chip module.

10. The method of claim 9, further comprising: coating at least a part of the backside of the semiconductor die so as to form a thermally highly conductive layer.
